(19) United States
(12) Patent Application Publication
(10) Pub. No.: US 2015/0229327 A1
(43) Pub. Date: Aug. 13, 2015

(54) MULTIPLEXER

(71) Applicant: FUJITSU LIMITED, Kawasaki-shi (JP)

(72) Inventor: Nikola NEDOVIC, San Jose, CA (US)

(73) Assignee: FUJITSU LIMITED, Kawasaki-shi (JP)

(21) Appl. No.: 14/179,341

(22) Filed: Feb. 12, 2014

(51) Int. Cl. H03M 9/00; H03K 5/13

(52) U.S. Cl. CPC H03M 9/00; H03K 5/13

(57) ABSTRACT

A multiplexer may include a first circuit, a second circuit, and a third circuit. The first circuit may be configured to receive a first input signal and a first trigger signal and to output a first output signal that may be based on the first input signal during a first level of the first trigger signal and may be at a known level during a second level of the first trigger signal. The second circuit may be configured to receive a second input signal and a second trigger signal and to output a second output signal that may be based on the second input signal during a first level of the second trigger signal and may be at the known level during a second level of the second trigger signal. The third circuit may be configured to output a third output signal based on the first and second output signals.

### FIELD

The embodiments discussed herein are related to multiplexers.

### BACKGROUND

Data serializers may be commonly found in various electronic devices. The function of a data serializer is to convert parallel data into a corresponding stream of serial data. Data serializers are sometimes used in integrated circuit devices where data may be coupled to or from an electronic device at a significantly faster rate than the data may be processed within the device. For example, in integrated memory devices, data may be coupled to or from a memory device at a rate that may be significantly faster than the rate at which the data may be serially processed in the memory device. In these cases, for example, read data may be provided by an array of memory cells in the memory device as a large number of parallel digits (e.g., bits), which are converted to a corresponding stream of serial data and output through a serial data port.

Although the design parameters of serializers may vary for different applications, two design parameters that may be considered for serializers are power consumption and operating speed. Operating speed may be important to allo read data to be transmitted from a memory device with a high data bandwidth. Low power consumption may be important in various applications, such as where a serializer is used in a battery-powered electronic system, such as a laptop computer, tablet, or other mobile device.

A particular form of serializer is often referred to as a “pipelined serializer.” A pipelined serializer essentially arranges multiple multiplexing circuits, which each include multiple latches and a clocked two-to-one multiplexer, into stages. Due to the latches within each multiplexing circuit, conventional pipelined serializers often contend with extensive clock routing, undesirably long latency values, large area penalties, large power consumption, and a critical path on the final multiplexing circuit that has a very short time constraint.

The subject matter claimed herein is not limited to embodiments that solve any disadvantages or that operate only in environments such as those described above. Rather, this background is only provided to illustrate one example technology area where some embodiments described herein may be practiced.

### SUMMARY

According to an aspect of an embodiment, a multiplexer includes a first circuit, a second circuit, and a third circuit. The first circuit may be configured to receive a first input signal and a first trigger signal and to output a first output signal on a first output node. The first output signal may be based on the first input signal during a first level of the first trigger signal and may be at a known level during a second level of the first trigger signal. The second circuit may be configured to receive a second input signal and a second trigger signal and to output a second output signal on a second output node. The second output signal may be based on the second input signal during a first level of the second trigger signal and may be at the known level during a second level of the second trigger signal. The second trigger signal may be an inversion of the first trigger signal. The third circuit may be coupled to the first and second output nodes and configured to output a third output signal based on the first and second output signals.

The object and advantages of the embodiments will be realized and achieved at least by the elements, features, and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

Example embodiments will be described and explained with additional specificity and detail through the use of the accompanying drawings in which:

FIG. 1A is a block diagram of an example multiplexer;

FIG. 1B illustrates an example timing diagram for the multiplexer of FIG. 1A;

FIG. 2 is a block diagram of an example circuit that may be included in the multiplexer of FIG. 1A;

FIG. 3 is a block diagram of another example circuit that may be included in the multiplexer of FIG. 1A;

FIG. 4 is a circuit diagram of an example multiplexer;

FIG. 5 is a block diagram of an example serializer; and

FIG. 6 is a flowchart of an example method of multiplexing parallel input signals.

### DESCRIPTION OF EMBODIMENTS

According to an aspect of an embodiment, a multiplexer is disclosed that includes a first circuit, a second circuit, and a third circuit. The first and second circuits may receive parallel data streams as input signals and first and second trigger signals (e.g., clock signals) that are inversions of one another. The first circuit may output data from its received data stream during a first level of the first trigger signal, such as when the first trigger signal is high. During a second level of the first trigger signal, such as when the first trigger signal is low, the first circuit may output a known level, such as a high signal.

The second circuit may output data from its received data stream during a first level of the second trigger signal, such as when the second trigger signal is high. During a second level of the second trigger signal, such as when the second trigger signal is low, the second circuit may output the known level. The first and second circuits may be configured so that when the first circuit outputs data from its received data stream, the second circuit outputs the known value, and when the second circuit outputs data from its received data stream, the first circuit outputs the known value.

The third circuit may be a logic circuit that receives the outputs from the first and second circuits. The logic circuit may be configured so that it outputs a value based on one of the received outputs when the other of the received outputs is the known value. The logic circuit thus outputs the data from the first and second circuits in a serial data stream, thereby multiplexing and serializing the parallel data streams received by the first and second circuits.

The above multiplexer is configured to multiplex and/or serialize two parallel data streams into a serial data stream faster than a conventional multiplexing circuit that includes one or more latches. As a result, the timing margins for the described multiplexer in a serializer may be improved as compared to timing margins for conventional multiplexing circuits in serializers. Furthermore, conventional multiplexing circuits typically have setup timing requirements, which involve how long data should be available at a circuit before a trigger signal (e.g., a clock) is received at the circuit, that are longer than setup timing requirements for the multiplexer described herein. In some embodiments, the multiplexer described herein may have a negative setup timing requirement, indicating that the data may be received by the multiplexer after the trigger signal. Additionally, the footprint and power usage of the multiplexer described herein may be smaller than the footprint and power usage of a conventional multiplexing circuit.

Embodiments of the present invention will be explained with reference to the accompanying drawings.

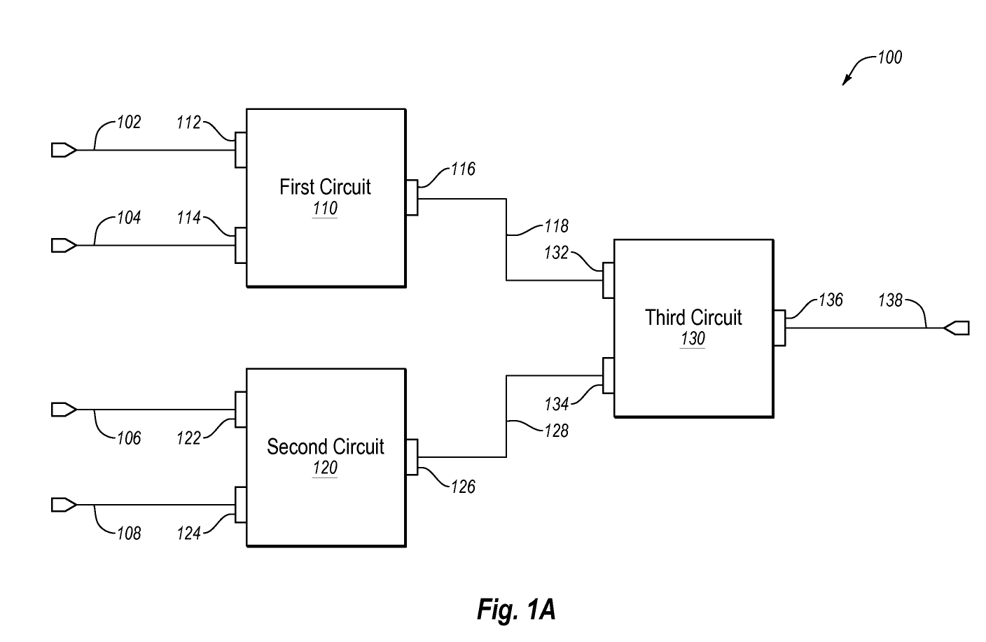

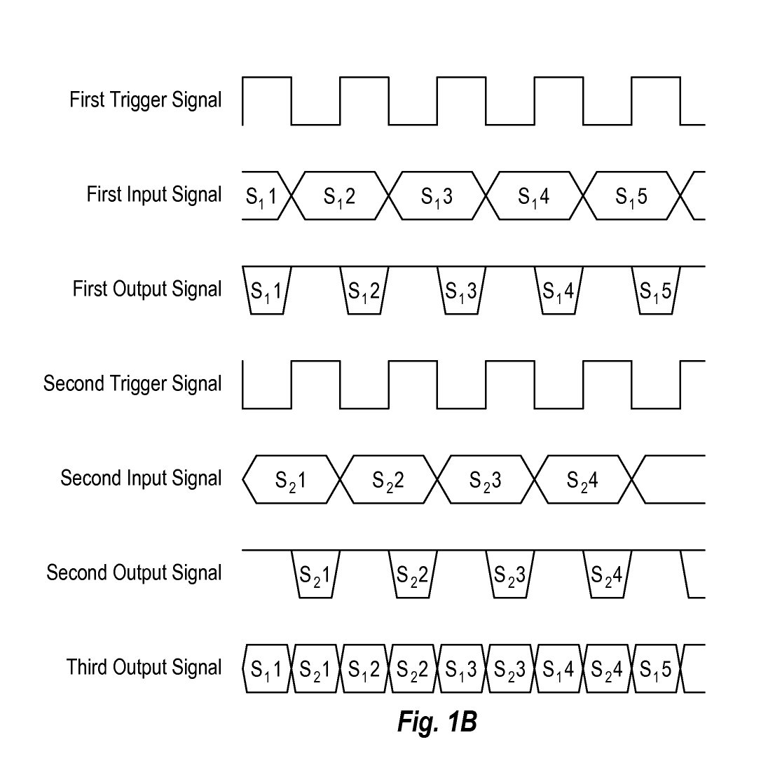

FIG. 1A is a block diagram of an example multiplexer 100, arranged in accordance with at least one embodiment described herein. The multiplexer 100 may include a first circuit 110, a second circuit 120, and a third circuit 130. The first circuit 110 may include a first input node 112, a second input node 114, and an output node 116. The second circuit 120 may include a first input node 122, a second input node 124, and an output node 126. The third circuit 130 may include a first input node 132, a second input node 134, and an output node 136. The output node 116 of the first circuit 110 may be communicatively coupled to the first input node 132 of the third circuit 130. The output node 126 of the second circuit 120 may be communicatively coupled to the second input node 134 of the third circuit 130.

The first input node 112 of the first circuit 110 may be configured to receive a first input signal 102. The first input signal 102 may be at a first level or a second level. For example, the first input signal 102 may be a logical high or a logical low. The first input signal 102 may be a single-ended data signal, a differential data signal, or some other type of signal or differential signal.

The second input node 114 of the first circuit 110 may be configured to receive a first trigger signal 104. The first trigger signal 104 may be at a first level or a second level. For example, the first trigger signal 104 may be a logical high or a logical low. The first trigger signal 104 may be a single-ended clock signal, a differential clock signal, or some other signal.

The first circuit 110 may be configured to generate a first output signal 118 and to output the first output signal 118 on the output node 116 of the first circuit 110. Outputting the first output signal 118 on the output node 116 of the first circuit 110 may provide the first output signal 118 to the first input node 132 of the third circuit 130.

The first circuit 110 may generate the first output signal 118 based on the first input signal 102 and the first trigger signal 104. In particular, during the first level of the first trigger signal 104, the first output signal 118 may be based on the first input signal 102. In some embodiments, the first output signal 118 may be the same level as the first input signal 102 or the first output signal 118 may be an inversion of the level of the first input signal 102. For example, when the first input signal 102 is a logical high, the first output signal 118 may be a logical high or a logical low, depending on the configuration of the first circuit 110.

During the second level of the first trigger signal 104, the first output signal 118 may be at a known level. For example, when the first trigger signal 104 is a logical high, the first output signal 118 is a logical high. In some embodiments, the first circuit 110 may be a sense amplifier. Alternately or additionally, the first circuit 110 may be some other type of circuit configured to generate the first output signal 118 as indicated herein.

FIG. 1B illustrates an example timing diagram for the multiplexer 100 of FIG. 1A, arranged in accordance with at least one embodiment described herein. In particular, FIG. 1B illustrates the timing of the first input signal 102, the first trigger signal 104, and the level of the first output signal 118. As illustrated in FIG. 1B, when the first trigger signal 104 is a logical low, the first output signal 118 is a logical high. Additionally, when the first trigger signal 104 is a logical high, the first output signal 118 is based on the level of the first input signal 102. Because the levels of the first input signal 102 may vary based on the data being carried by the first input signal 102, the levels are depicted as S₁1, S₁2, S₁3, S₁4, and S₁5. The first output signal 118 may have a data rate that is approximately equal to the data rate of the first input signal 102 even though the first output signal 118 is at the known level for a portion of each unit interval of the first output signal 118.

Returning to FIG. 1A, the first input node 122 of the second circuit 120 may be configured to receive a second input signal 106. The second input signal 106 may be at a first level or a second level. For example, the second input signal 106 may be a logical high or a logical low. The second input signal 106 may be a single-ended data signal, a differential data signal or some other type of single-ended signal or differential signal. In some embodiments, the first input signal 102 and the second input signal 106 may be parallel data signals or streams.

The second input node 114 of the second circuit 120 may be configured to receive a second trigger signal 108. The second trigger signal 108 may be at a first level or a second level. For example, the second trigger signal 108 may be a logical high or a logical low. The second trigger signal 108 may be an inversion of the first trigger signal 104. As a result, when the second trigger signal 108 is a logical high, the first trigger signal 104 may be a logical low and when the second trigger signal 108 is a logical low, the first trigger signal 104 may be logical high.

The second trigger signal 108 may be a single-ended clock signal, a differential clock signal, or some other single-ended signal or differential signal. In some embodiments, the second trigger signal 108 may be one clock signal of a differential clock signal and the first trigger signal 104 may be another clock signal of the differential clock signal.

The second circuit 120 may be configured to generate a second output signal 128 and to output the second output signal 128 on the output node 126 of the second circuit 120. Outputting the second output signal 128 on the output node 126 of the second circuit 120 may provide the second output signal 128 to the second input node 134 of the third circuit 130.

The second circuit 120 may generate the second output signal 128 based on the second input signal 106 and the second trigger signal 108. In particular, during the first level of the second trigger signal 108, the second output signal 128 may be based on the second input signal 106. In some embodiments, the second output signal 128 may be at a same level of the second input signal 106 or the second output signal 128 may be an inversion of the level of the second input signal 106. For example, when the second input signal 106 is a logical high, the second output signal 128 may be a logical high or a logical low, depending on the configuration of the second circuit 120.

During the second level of the second trigger signal 108, the second output signal 128 may be at the known level. The known level for the second output signal 128 may be the same as the known level for the first output signal 118. As a result of the first trigger signal 104 and the second trigger signal 108 being inversions of one another, the second output signal 128 and the first output signal 118 are typically not at the known level at the same time. Rather, when the second output signal 128 is based on the second input signal 106, the first output signal 118 is at the known level and when the first output signal 118 is based on the first input signal 102, the second output signal 128 is at the known level.

In some embodiments, the second circuit 120 may be a sense amplifier. Alternately or additionally, the second circuit 120 may be some other type of circuit configured to generate the second output signal 128 as indicated herein.

FIG. 1B also illustrates the timing of the second input signal 106, the second trigger signal 108, and the level of the second output signal 128. As illustrated in FIG. 1B, when the second trigger signal 108 is a logical low, the second output signal 128 is a logical high. Additionally, when the second trigger signal 108 is a logical high, the second output signal 128 is based on the level of the second input signal 106. Because the levels of the second input signal 106 may vary based on the data being carried by the second input signal 106, the levels are depicted as S₂1, S₂2, S₂3, and S₂4. The second output signal 128 may have a data rate that may be approximately equal to the data rate of the second input signal 106 even though the second output signal 128 is at the known level for a portion of each unit interval of the second output signal 128.

Returning to FIG. 1A, the first input node 132 of the third circuit 130 may be configured to receive the first output signal 118 from the first circuit 110. The second input node 134 of the third circuit 130 may be configured to receive the second output signal 128 from the second circuit 120.

The third circuit 130 may be configured to generate a third output signal 138 based on the first and second output signals 118 and 128 and to output the third output signal 138 out of an output node 136 of the third circuit 130. The third output signal 138 may be a differential signal or a single-ended signal.

The third circuit 130 may be configured such that when one of the first and second output signals 118 and 128 is at the known level, the third circuit 130 bases the third output signal 138 on the other of the first and second output signals 118 and 128. For example, when the first output signal 118 is based on the first input signal 102 and the second output signal 128 is at the known level, the third output signal 138 is based on the first input signal 102. Additionally, when the second output signal 128 is based on the second input signal 106 and the first output signal 118 is at the known level, the third output signal 138 is based on the second input signal 106. As a result, the third output signal 138 combines (e.g., serializes) the first and second input signals 102 and 106, with the third output signal 138 having a data rate that is twice the data rates of the first and second input signals 102 and 106. FIG. 1B illustrates how the third output signal 138 combines the first and second input signals 102 and 106.

In some embodiments, the third circuit 130 may be a logic gate or a combination of logic gates. In some embodiments, where the third output signal 138 is a differential signal, the third circuit 130 may be two logic gates. In these and other embodiments, the two logic gates may be similar. One of the logic gates may handle one signal from each of the differential first and second output signals 118 and 128 and the other logic gate may handle the other signal from each of the differential first and second output signals 118 and 128.

In some embodiments, the third circuit 130 may be a NAND logic gate. In these and other embodiments, the known level of the first and second output signals 118 and 128 may be logical high. In some embodiments, the third circuit 130 may be a NOR logic gate. In these and other embodiments, the known level of the first and second output signals 118 and 128 may be logical low.

In some embodiments, the first output signal 118 may be an inversion of the first input signal 102 and the second output signal 128 may be an inversion of the second input signal 106. In these and other embodiments, the third circuit 130 may invert the first output signal 118 and the second output signal 128 such that the third output signal 138 is a combination of the non-inverted first and second input signals 102 and 106. Alternately or additionally, the third circuit 130 may not invert the first output signal 118 and the second output signal 128 such that the third output signal 138 is a combination of the inverted first and second input signals 102 and 106.

Modifications, additions, or omissions may be made to the multiplexer 100 without departing from the scope of the present disclosure.

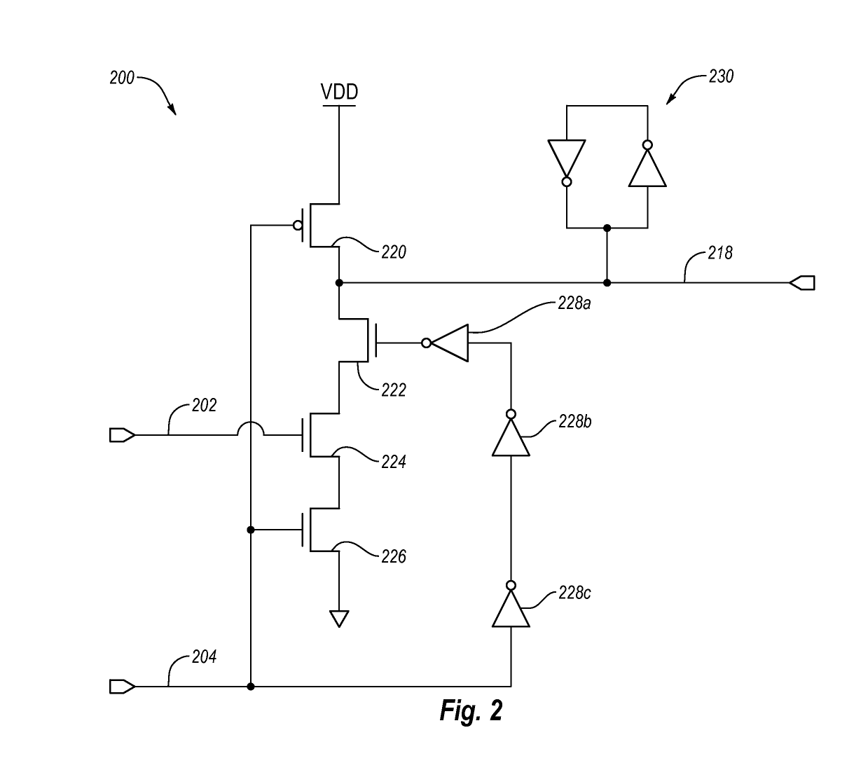

FIG. 2 is a block diagram of an example circuit 200 that may be included in the multiplexer 100 of FIG. 1A, arranged in accordance with at least one embodiment described herein. The circuit 200 may be configured to receive an input signal 202 and a trigger signal 204. Based on the input signal 202 and the trigger signal 204, the circuit 200 may be configured to generate an output signal 218.

In some embodiments, the circuit 200 may be used in place of either the first circuit 110 or the second circuit 120 of FIG. 1. In these and other embodiments, the input signal 202 may be analogous to the first or second input signals 102 and 106 of FIG. 1, the trigger signal 204 may be analogous to the first or second trigger signals 104 and 108 of FIG. 1, and the output signal 218 may be analogous to the first or second output signals 118 and 128 of FIG. 1.

The input signal 202 may be a single-ended signal that may have a level that is either a logical high or a logical low. The trigger signal 204 may be a single-ended clock signal with an approximately 50% duty cycle that alternates between logical high and logical low.

The circuit 200 may include a first transistor 220, a second transistor 222, a third transistor 224, a fourth transistor 226, first, second, and third inverters 228a, 228b, and 228c, collectively the inverters 228, and a holding circuit 230. The first transistor 220, the second transistor 222, the third transistor 224, the fourth transistor 226, the inverters 228, and the holding circuit 230 may be coupled as illustrated in FIG. 2.

A brief explanation of the functionality of the circuit 200 is now provided. When the trigger signal 204 is a logical low, the trigger signal 204 actuates the first transistor 220 and deactuates the fourth transistor 226, coupling the output signal 218 to VDD to cause the output signal 218 to be a logical high. The output signal 218 is a logical high regardless of the level of the input signal 202 because the fourth transistor 226 is deactuated from the trigger signal 204, thereby not allowing the output signal 218 to be pulled to a logical low.

When the trigger signal 204 is a logical high, the output signal 218 may be an inverted level of the input signal 202. For example, when the trigger signal 204 is a logical high and the input signal 202 is a logical high, the output signal 218 may be a logical low. When the trigger signal 204 is a logical high and the input signal 202 is a logical high, the third and fourth transistors 224 and 226 are actuated and the first transistor 220 is deactuated. When the trigger signal 204 first transitions to the logical high, the second transistor 222 may also be actuated. For a period of time equal to the delay through the inverters 228, the output signal 218 is coupled to ground to cause the output signal 218 to be a logical low. After the transition of the trigger signal 204 reaches the second transistor 222, the second transistor 222 deactuates, decoupling the output signal 218 from ground. Thus, the output signal 218 is decoupled from ground and VDD. In this embodiment, the holding circuit 230 holds the output signal 218 at the logical low level.

As another example, when the trigger signal 204 is a logical low and the input signal 202 is a logical high, the output signal 218 may be a logical high. When the trigger signal 204 is a logical high and the input signal 202 is a logical low, the first and third transistors 220 and 224 are deactuated, resulting in the output signal 218 being decoupled from ground and VDD. At the previous level of the output signal 218, which is the known level, the logical high is maintained on the output signal 218 by the holding circuit 230.

Modifications, additions, or omissions may be made to the circuit 200 without departing from the scope of the present disclosure. For example, in some embodiments, the circuit 200 may include additional inverters 228. Alternately or additionally, the holding circuit 230 may include other circuit elements than those illustrated in FIG. 2.

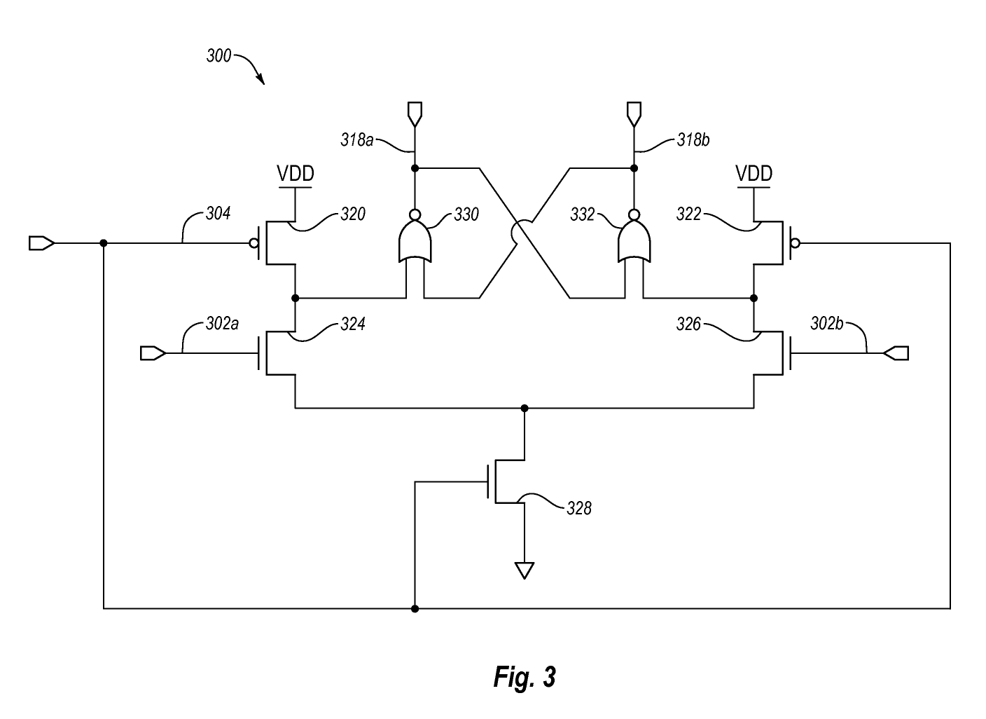

FIG. 3 is a block diagram of another example circuit 300 that may be included in the multiplexer 100 of FIG. 1A, arranged in accordance with at least one embodiment described herein. The circuit 300 may be configured to receive a differential input signal that includes input signal A 302a and input signal B 302b, referred to collectively as an input signal 302, and a trigger signal 304. The input signal 302 may have a level that is either a logical high or a logical low. The trigger signal 304 may be a single-ended clock with an approximately 50% duty cycle that alternates between a logical high and a logical low.

Based on the input signal 302 and the trigger signal 304, the circuit 300 may be configured to generate a differential output signal that includes output signal A 318a and output signal B 318b, referred to collectively as the output signal 318.

In some embodiments, the circuit 300 may be used in place of either the first circuit 110 or the second circuit 120 of FIG. 1. In these and other embodiments, the input signal 302 may be analogous to the first or second input signals 102 and 106 of FIG. 1, the trigger signal 304 may be analogous to the first or second trigger signals 104 and 108 of FIG. 1, and the output signal 318 may be analogous to the first or second output signals 118 and 128 of FIG. 1.

The circuit 300 may include a first transistor 320, a second transistor 322, a third transistor 324, a fourth transistor 326, a fifth transistor 328, a first NOR gate 330, and a second NOR gate 332. The first transistor 320, the second transistor 322, the third transistor 324, the fourth transistor 326, the fifth transistor 328, the first NOR gate 330, and the second NOR gate 332 may be coupled as illustrated in FIG. 3.

A brief explanation of the functionality of the circuit 300 is now provided. When the trigger signal 304 is a logical low, the first and second transistors 320 and 322 may be actuated causing both the first and second NOR gates 330 and 332 to receive a logical high. When the first and second NOR gates 330 and 332 receive a logical high on either of their inputs, the first and second NOR gates 330 and 332 output a logical low as their respective output signals A and B 318a and 318b.

When the trigger signal 304 is a logical high, the output signal 318 may be the input signal 302. For example, when the trigger signal 304 is a logical high, the input signal A 302a is a logical high, and the input signal B 302b is a logical low, the output signal A 318a may be a logical high and the output signal B 318b may be a logical low. When the trigger signal 304 is a logical high, the input signal A 302a is a logical high, and the input signal B 302b is a logical low, the third and fifth transistors 324 and 328 are actuated and the first, second, and fourth transistors 320, 322, and 326 are deactuated causing the first NOR gate 330 to be coupled to ground and receive a logical low on one input. The other input of the first NOR gate 330 also has a logical low that is being output by the second NOR gate 332 based on when the trigger signal 304 was a logical low previous to the trigger signal 304 transitioning to the logical high. With the first NOR gate 330 having a logical low on both inputs, the NOR gate 330 outputs a logical high as the output signal A 318a. The second NOR gate 332 receives the logical high output from the first NOR gate 330 and outputs a logical low as the output signal B 318b.

Modifications, additions, or omissions may be made to the circuit 300 without departing from the scope of the present disclosure. For example, in some embodiments, the first and second NOR gates 330 and 332 may be different types of logic gates, such as NAND gates.

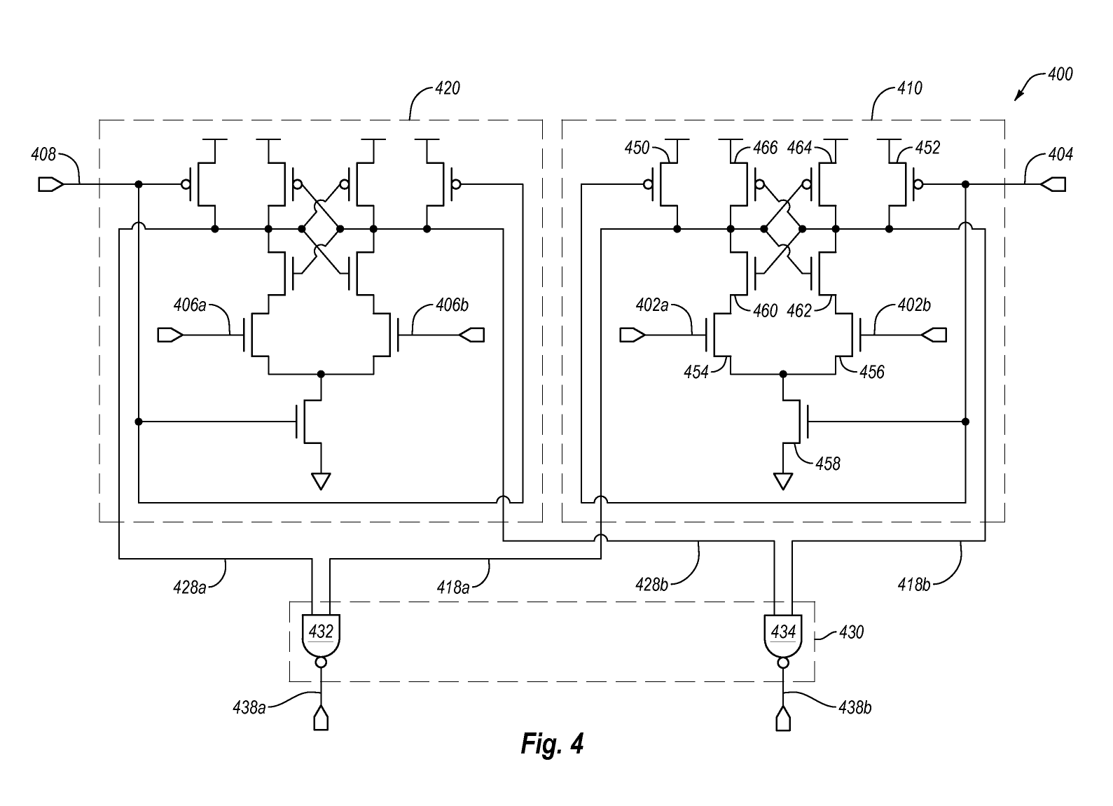

FIG. 4 is a circuit diagram of an example multiplexer 400, arranged in accordance with at least one embodiment described herein. The multiplexer 400 may include a first circuit 410, a second circuit 420, and a third circuit 430. The multiplexer 400 may be analogous to the multiplexer 100 of FIG. 1. Accordingly, the first circuit 410, the second circuit 420, and the third circuit 430 may be analogous to the first, second, and third circuits 110, 120, and 130, respectively, of FIG. 1.

The first circuit 410 may be configured to receive a first input signal 402, which may be a differential input signal that includes a first input signal A 402a and a first input signal B 402b. The first circuit 410 may also be configured to receive a first trigger signal 404. Based on the first trigger signal 404 and the first input signal 402, the first circuit 410 may be configured to generate a first output signal 418, which may be a differential output signal that includes a first output signal A 418a and a first output signal B 418b. The first circuit 410 may provide the first output signal 418 to the third circuit 430. In particular, the first circuit 410 may provide the first output signal A 418a and the first output signal B 418b to a first NAND gate 432 and to second NAND gate 434, respectively, of the third circuit 430.

The first circuit 410 may be configured to generate the first output signal 418 based on the first input signal 402 and the first trigger signal 404. In particular, when the first trigger signal 404 is a logical high, the first output signal 418 may be based on the first input signal 402. For example, when the first input signal A 402 is a logical high and the first input signal B 402b is a logical low, the first output signal A 418a may be a logical low and the first output signal B 418b may be a logical high. Furthermore, when the first input signal A 402 is a logical low and the first input signal B 402b is a logical high, the first output signal A 418a may be a logical high and the first output signal B 418b may be a logical low.

When the first trigger signal 404 is a logical low, the first output signal 418 may be a logical low, which may be a known level for the multiplexer 400. In particular, the first output signal A 418a and the first output signal B 418b may both be a logical low.

The first circuit 410 may include a first transistor 450, a second transistor 452, a third transistor 454, a fourth transistor 456, a fifth transistor 458, a sixth transistor 460, a seventh transistor 462, an eighth transistor 464, and a ninth transistor 466. The first transistor 450, the second transistor 452, the third transistor 454, the fourth transistor 456, the fifth transistor 458, the sixth transistor 460, the seventh transistor 462, the eighth transistor 464, and the ninth transistor 466 may be coupled as illustrated in FIG. 4.

A brief explanation of the functionality of the first circuit 410 is now provided. When the first trigger signal 404 is a logical low, the first trigger signal 404 actuates the first and second transistors 450 and 452 and deactuates the fifth transistor 458. By actuating the first and second transistors 450 and 452, the first output signals A and B 418a and 418b are coupled to VDD to cause the first output signals A and B 418a and 418b to be the known level of a logical high. The first output signals A and B 418a and 418b may be a logical high regardless of the level of the first input signal 402 because the fifth transistor 458 is deactuated by the first trigger signal 404, thereby not allowing the first output signals A and B 418a and 418b to be pulled to ground.

When the first trigger signal 404 is a logical high, the first input signal A 402a is a logical high, and the first input signal B 402b is a logical low, the first, second, and fourth transistors 450, 452, and 456 are deactuated and the third and fifth transistors 454 and 458 are actuated. As the first trigger signal 404 is transitioning to a logical high from a logical low, the first output signals A and B 418a and 418b are a logical high as described above. As a result, the sixth and seventh transistors 460 and 462 are actuated and the eighth and ninth transistors 464 and 466 are deactuated. When the first trigger signal 404 transitions to a logical high and the first input signal A 402a is a logical high, the first output signal A 418a is pulled to ground through the third, fifth, and sixth transistors 454, 458, 460. When the first output signal A 418a is pulled to ground, a logical low, the first output signal A 418a deactuates the seventh transistor 462 and actuates the ninth transistor 466 pulling the first output signal B 418b to VDD, a logical high. As a result, the first circuit 410 inverts the first output signals A and B 418a and 418b with respect to the first input signal A 402a and the first input signal B 402b.

The second circuit 420 may be configured to receive a second input signal 406, which may be a differential input signal that includes a second input signal A 406a and a second input signal B 406b. The second circuit 420 may also be configured to receive a second trigger signal 408. The second trigger signal 408 may be an inversion of the first trigger signal 404. As a result, when the second trigger signal 408 is a logical high, the first trigger signal 404 is a logical low and vice versa.

Based on the second trigger signal 408 and the second input signal 406, the second circuit 420 may be configured to generate a second output signal 428, which may be a differential output signal that includes a second output signal A 428a and a second output signal B 428b. In particular, when the second trigger signal 408 is a logical high, the second output signal 428 may be based on the second input signal 406. For example, when the second input signal A 406a is a logical high and the second input signal B 406b is a logical low, the second output signal A 428a may be a logical low and the second output signal B 428b may be a logical high. Furthermore, when the second input signal A 406a is a logical low and the second input signal B 406b is a logical high, the second output signal A 428a may be a logical high and the second output signal B 428b may be a logical low.

When the second trigger signal 408 is a logical low, the second output signal 428 may be logical low, which may be the known level. In particular, the second output signal A 428a and the second output signal B 428b may both be a logical low.

The second circuit 420 may provide the second output signal 428 to the third circuit 430. In particular, the second circuit 420 may provide the second output signal A 428a and the second output signal B 428b to the first NAND gate 432 and to the second NAND gate 434, respectively, of the third circuit 430.

The second circuit 420 may be configured to include nine transistors as illustrated in FIG. 4, which are configured and operate in an analogous manner as the transistors of the first circuit 410.

The third circuit 430 may be configured to generate a third output signal 438, which may be a differential output signal that includes a third output signal A 438a and a third output signal B 438b. The third circuit 430 may include the first NAND gate 432 and to the second NAND gate 434.

The first NAND gate 432 may be configured to receive the first output signal A 418a from the first circuit 410 and to receive the second output signal A 428a from the second circuit 420. Based on the first output signal A 418a and the second output signal A 428a, the first NAND gate 432 may generate the third output signal A 438a.

As discussed above, the first and second output signals A 418a and 428a provided to the first NAND gate 432 alternate between being at the known level, which is a logical high, and being based on the first and second input signals A 402a and 406a, respectively. With one of the first and second output signals A 418a and 428a being a logical high, the first NAND gate 432 inverts the other of the first and second output signals A 418a and 428a and outputs the inverted other of the first and second output signals A 418a and 428a as the third output signal A 438a. The first and second output signals A 418a and 428a may be inverted by the first and second circuits 410 and 420. As such, the third output signal A 438a is a function of the combination of the first and second input signals A 402a and 406a, where the third output signal A 438a has a date rate that is approximately twice the data rate of the first and second input signals A 402a and 406a. The second NAND gate 434 may be configured to generate the third output signal B 438b based on the first output signal B 418b and the second output signal B 428b in a manner analogous to how the first NAND gate 432 generates the third output signal A 438a. Modifications, additions, or omissions may be made to the multiplexer 400 without departing from the scope of the present disclosure.

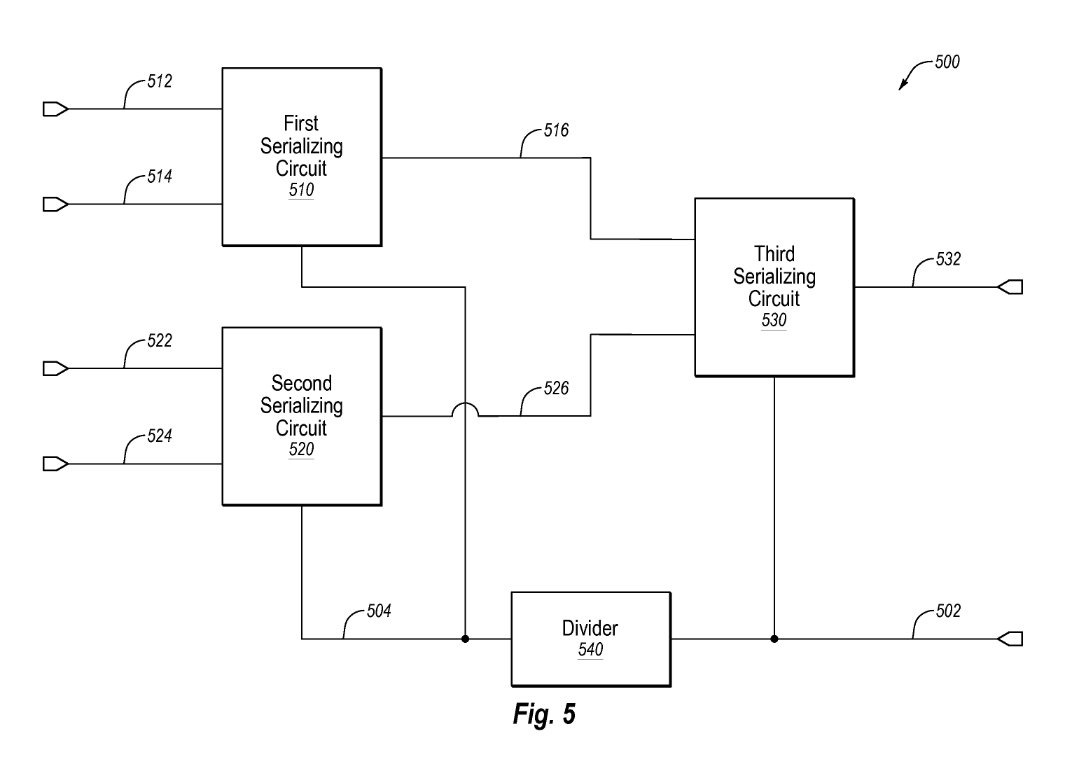

FIG. 5 is a block diagram of an example serializer 500, arranged in accordance with at least one embodiment described herein. The serializer 500 may include a first serializing circuit 510, a second serializing circuit 520, a third serializing circuit 530, and a divider 540. The first and second serializing circuits 510 and 520 may be communicatively coupled to the third serializing circuit 530.

The serializer 500 may be configured to receive multiple parallel bit streams, for example, the serializer 500 may be configured to receive first, second, third, and fourth bit streams 512, 514, 522, and 524. The first, second, third, and fourth bit streams 512, 514, 522, and 524 may be parallel in that they all provide data at approximately the same data rate in a parallel manner. The serializer 500 may be configured to output a serial bit stream 532 that is a serialization of the parallel bit streams 512, 514, 522, and 524.

The divider 540 may be configured to receive a clock signal 502 and to divide the clock signal 502 into a divided clock signal 504 that has a frequency less than the frequency of the clock signal 502. In some embodiments, the divided clock signal 504 may have a frequency that is half the frequency of the clock signal 502. In some embodiments, the clock signal 502 and the divided clock signal 504 may be single-ended or differential clock signals.

The first serializing circuit 510 may be configured to receive the first and second bit streams 512 and 514 and the divided clock signal 504 and to generate a first intermediate serial bit stream 516 using the first and second bit streams 512 and 514 and the divided clock signal 504. The first intermediate serial bit stream 516 may be generated by multiplexing the first and second bit streams 512 and 514 into the first intermediate serial bit stream 516 based on logical high and low levels of the divided clock signal 504. For example, the first intermediate serial bit stream 516 may be formed by interweaving alternate data symbols from the first and second bit streams 512 and 514. In some embodiments, the first intermediate serial bit stream 516 may have a data rate that is twice the data rate of the first and second bit streams 512 and 514.

The second serializing circuit 520 may be configured to receive the third and fourth bit streams 522 and 524 and the divided clock signal 504 and to generate a second intermediate serial bit stream 526 using the third and fourth bit streams 522 and 524 and the divided clock signal 504. The second serializing circuit 520 may operate in an analogous manner as the first serializing circuit 510.

The third serializing circuit 530 may be configured to receive the first and second intermediate serial bit streams 516 and 526 and the divided clock signal 504 and to generate the serial bit stream 532 using the first and second intermediate serial bit streams 516 and 526 and the clock signal 502. The third serializing circuit 530 may operate in an analogous manner as the first and second serializing circuits 510 and 520. In some embodiments, the serial bit stream 532 may have a data rate that is twice the data rate of the first and second intermediate serial bit streams 516 and 526.

In some embodiments, one or more of the first, second, or third serializing circuits 510, 520, and 530 may be the multiplexer 100 or 400 of FIGS. 1 and 4. Alternately or additionally, one or more of the first, second, or third serializing circuits 510, 520, and 530 may be known multiplexing circuits that include one more latches. In some embodiments, the third serializing circuit 530 may have a timing constraint that is less than the timing constraint of the first and second serializing circuits 510 and 520 due to the clock signal 502 operating at a higher frequency than the divided clock signal 504. In these and other embodiments, the third serializing circuit 530 may be the multiplexer 100 or 400 of FIGS. 1 and 4 and the first and second serializing circuits 510 and 520 may be other known multiplexing circuits. The third serializing circuit 530 may be the multiplexer 100 or 400 of FIGS. 1 and 4 because the multiplexer 100 or 400 of FIGS. 1 and 4 may operate faster than other known multiplexing circuits enabling the third serializing circuit 530 to more easily meet the more rigid time constraints associated with the higher frequency clock signal 502.

Modifications, additions, or omissions may be made to the serializer 500 without departing from the scope of the present disclosure. For example, in some embodiments, the serializer 500 may include additional serializing circuits. In these and other embodiments, the serializer 500 may serialize eight parallel data streams using seven serializing circuits. In these and other embodiments, all of or a portion of the serializing circuit may include the multiplexers 100 or 400 of FIGS. 1 and 4.

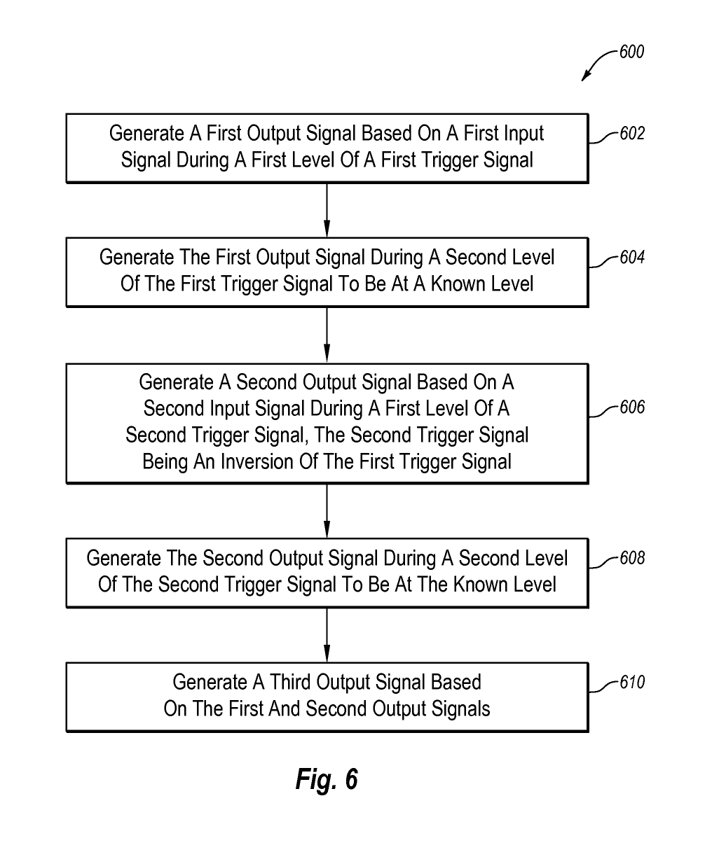

FIG. 6 is a flowchart of an example method 600 of multiplexing parallel input signals, arranged in accordance with at least one embodiment described herein. The method 600 may be implemented, in some embodiments, by a multiplexer or a serializer, such as the multiplexer 100 or 400 of FIGS. 1 and 4 or the serializer 500 of FIG. 5, respectively. Although illustrated as discrete blocks, various blocks may be divided into additional blocks, combined into fewer blocks, or eliminated, depending on the desired implementation.

The method 600 may begin at block 602, where a first output signal may be generated based on a first input signal during a first level of a first trigger signal. In some embodiments, the first output signal may be an inversion of the first input signal during the first level of the first trigger signal.

In block 604, the first output signal may be generated during a second level of the first trigger signal to be at a known level.

In block 606, a second output signal may be generated based on a second input signal during a first level of a second trigger signal. The second trigger signal may be an inversion of the first trigger signal. In some embodiments, the second output signal may be an inversion of the second input signal during the first level of the second trigger signal.

In block 608, the second output signal may be generated during a second level of the second trigger signal to be at the known level.

In block 610, a third output signal may be generated based on the first and second output signals. In some embodiments, the third output signal may be the first input signal when the second output signal is the known level. Alternately or additionally, the third output signal may be the second input signal when the first output signal is at the known level. In some embodiments, the third output signal may be an inversion of either or both the first output signal and the second output signal.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

All examples and conditional language recited herein are intended for pedagogical objects to aid the reader in understanding the invention and the concepts contributed by the inventor to furthering the art, and are to be construed as being without limitation to such specifically recited examples and conditions. Although embodiments of the present inventions have been described in detail, it should be understood that the various changes, substitutions, and alterations could be made hereto without departing from the spirit and scope of the invention.

What is claimed is:

1. A multiplexer comprising:
a first circuit configured to receive a first input signal and a first trigger signal and to output a first output signal on a first output node, the first output signal being based on the first input signal during a first level of the first trigger signal and being at a known level during a second level of the first trigger signal;
a second circuit configured to receive a second input signal and a second trigger signal and to output a second output signal on a second output node, the second output signal being based on the second input signal during a first level of the second trigger signal and being at the known level during a second level of the second trigger signal, the second trigger signal being an inversion of the first trigger signal; and
a third circuit coupled to the first output node and the second output node and configured to output a third output signal based on the first and second output signals.

2. The multiplexer of claim 1, wherein the third output signal is the first input signal when the second output signal is at the known level and the third output signal is the second input signal when the first output signal is at the known level.

3. The multiplexer of claim 1, wherein the first level of the first trigger signal and the first level of the second trigger signal are logic high levels or logic low levels.

4. The multiplexer of claim 1, wherein the known level is a logic high level or a logic low level.

5. The multiplexer of claim 4, wherein the third circuit comprises at least one NAND gate when the known level is the logic high level and the third circuit comprises at least one NOR gate when the known level is the logic low level.

6. The multiplexer of claim 1, wherein during the first level of the first trigger signal the first output signal is an inversion of the first input signal and during the first level of the second trigger signal the second output signal is an inversion of the second input signal.

7. The multiplexer of claim 6, wherein the third output signal is an inversion of either or both the first output signal and the second output signal.

8. The multiplexer of claim 1, wherein the first input signal and the second input signal are part of a parallel signal.

9. The multiplexer of claim 1, wherein the first trigger signal and the second trigger signal form a differential trigger signal.

10. The multiplexer of claim 1, wherein the first trigger signal and the second trigger signal are clock signals.

11. The multiplexer of claim 1, wherein at least one of the first circuit and the second circuit is a sense amplifier.

12. A serializer comprising:
a plurality of serializing circuits configured to generate an output serial bit stream from a plurality of parallel bit streams, wherein at least one of the plurality of serializing circuits is a non-latched serializing circuit that comprises:
a first circuit configured to receive a first parallel bit stream of the plurality of bit streams and a first clock signal and to output a first output bit stream on a first output node, the first output bit stream being based on the first parallel bit stream during a first level of the first clock signal and being at a known level during a second level of the first clock signal;
a second circuit configured to receive a second parallel bit stream of the plurality of bit streams and a second clock signal and to output a second output bit stream on a second output node, the second output bit stream being based on the second parallel bit stream during a first level of the second clock signal and being at a known level during a second level of the second clock signal, the second clock signal being an inversion of the first clock signal; and
a third circuit coupled to the first output node and the second output node and configured to output a serial bit stream by combining the first and second output bit streams.

13. The serializer of claim 12, wherein each of the plurality of serializing circuits is configured to combine at least two of the plurality of parallel bit streams.

14. The serializer of claim 12, wherein the serial bit stream output by the non-latched serializing circuit is the output serial bit stream output by the serializer.

15. The serializer of claim 12, wherein each of the plurality of serializing circuits are formed as the non-latched serializing circuit.

16. The serializer of claim 12, wherein the first clock signal and the second clock signal form a differential clock signal.

17. A method of multiplexing parallel input signals, the method comprising:
generating a first output signal based on a first input signal during a first level of a first trigger signal;
generating the first output signal during a second level of the first trigger signal to be at a known level;
generating a second output signal based on a second input signal during a first level of a second trigger signal, the second trigger signal being an inversion of the first trigger signal;
generating the second output signal during a second level of the second trigger signal to be at the known level; and
generating a third output signal based on the first and second output signals.

18. The method of claim 17, wherein the third output signal is the first input signal when the second output signal is at the known level and the third output signal is the second input signal when the first output signal is at the known level.

19. The method of claim 17, wherein the first output signal is an inversion of the first input signal during the first level of the first trigger signal and the second output signal is an inversion of the second input signal during the first level of the second trigger signal.

20. The method of claim 19, wherein the third output signal is an inversion of either or both the first output signal and the second output signal.
